(19) United States
(12) Patent Application Publication
(10) Pub. No.: US 2007/0037378 A1
(43) Pub. Date: Feb. 15, 2007

(54) Method for forming metal pad in semiconductor device

(75) Inventor: Sung Joong Joo, Incheon (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd

(21) Appl. No.: 11/502,364

(22) Filed: Aug. 11, 2006

(30) Foreign Application Priority Data
Aug. 11, 2005 (KR) 10-2005-0073842

(51) Int. Cl. H01L 21/44; H01L 21/4763

(52) U.S. Cl. 438/614; 438/622; 257/E23.02

(57) ABSTRACT

A method for manufacturing a metal pad connected to a metal line in a semiconductor device is provided. The method includes forming an interlevel dielectric (ILD) layer on a substrate; forming at least one metal line on the ILD layer; forming a metal barrier on the ILD layer and the metal line; reforming the surface of the metal barrier by performing a reforming process using an inert gas; and forming a metal pad on the metal barrier.

This application claims the benefit of priority to Korean Application No. 10-2005-0073842, filed on Aug. 11, 2005, which is incorporated by reference herein in its entirety.

### BACKGROUND

1. Technical Field

The present invention relates to a method for manufacturing a semiconductor device. More specifically, the present invention relates to a method for manufacturing a metal pad connected to a metal line in a semiconductor device.

2. Description of the Related Art

According to the trend of highly integrated semiconductor devices having its design rule of 130 nm or below, a wiring in semiconductor devices is formed using a damascene (or dual damascene) process. Generally, Cu, which has a lower resistivity and a higher reliability than Al, is used as a material for a metal line. However, it is hard to form fine Cu patterns by using a dry-etching process because of the difficulties involved in forming highly volatile chemical compounds.

Recently, a damascene process has been developed to form a metal line in semiconductor devices using Cu. In a typical Cu damascene process, an ILD (Interlevel Dielectric) layer is etched to form a wiring area (i.e., a trench); the trench is filled with a Cu material; and then the ILD layer is planarized using a CMP process, thus forming a Cu metal line. In a dual damascene process, a trench and a contact hole (also referred to a via hole) are formed by etching an ILD layer; the trench and the contact hole are filled with a Cu material; and the surface of the ILD layer is planarized using CMP process, thus forming a contact and a metal line at once by one CMP process.

On the other hand, usually, a metal pad in semiconductor devices is formed with Al instead of Cu in consideration of the adhesiveness with a bonding wire for a connection with an external circuit. Thus, an Al metal pad is formed on a Cu metal line formed by damascene process. In the case where a Cu metal line is connected with an Al metal pad, a metal barrier may additionally be formed between the Cu metal line and the Al metal pad. The reasons this is performed are to avoid diffusion of Cu ions into the metal pad, and to avoid peeling off the metal pad from the metal line due to the weak adhesion between an Al metal pad and the Cu metal line when forming a bonding wire in the metal pad.

FIG. 1 is a flow chart illustrating a conventional method for manufacturing a metal pad in a semiconductor device. FIGS. 2A to 2D are cross-sectional views illustrating processes for manufacturing a metal pad in a semiconductor device, according to the conventional method. Referring to these drawings, the conventional method for manufacturing a metal pad in a semiconductor device will be explained in detail.

Firstly, as shown in FIG. 2A, an ILD (Interlevel Dielectric) layer 12 such as a TEOS (Tetraethylorthosilicate) oxide layer, an HDP (High Density Plasma) oxide layer, etc., is formed on_a semiconductor substrate in which a predetermined structure including a lower metal line 10 is formed, using a CVD (Chemical Vapor Deposition) or PVD (Physical Vapor Deposition) process. Here, the lower metal line 10 can be formed of Cu, Al, or other metal materials. Also, the predetermined structure in a semiconductor substrate may include a semiconductor device such as MOS transistor, and the like.

Subsequently, using a mask having an opening that defines a contact hole and a trench in a dual damascene structure, a trench and a contact hole are formed by etching ILD layer 12 using photolithography and etching processes. Then, using an electroplating method, etc., the trench and the contact hole formed on ILD layer 12 are gap-filled with a Cu material, and then the ILD layer 12 is planarized using a CMP process until a surface thereof is exposed, thus forming an upper Cu metal line 16 and a contact 14 perpendicularly connected to the lower metal line 10 (step S10 of FIG. 1).

Subsequently, as shown in FIG. 2B, a metal barrier 18, e.g., TiSiN, is formed on the ILD layer 12 and the Cu metal line 16 using a PVD process (e.g., plasma sputtering deposition). (step S20 of FIG. 1).

Then, as shown in FIG. 2C, an Al layer for a metal pad 20 is formed on the metal barrier 18 using a PVD process (step S30 of FIG. 1).

Subsequently, as shown in FIG. 2D, an Al metal pad 20, which is connected to the Cu metal line 16 with the metal barrier 18 interposed therebetween, is formed by patterning the Al layer and the metal barrier 18, using conventional photolithography and etching processes.

In the conventional method for manufacturing a metal pad in a semiconductor device according to the above-described prior art, a deposition process for forming a metal pad 20 is performed in-situ after the deposition of the metal barrier 18. Because the depositing temperature (about 350° C.) of TiSiN, which is used as the metal barrier 18, is high, Cu ions in the Cu metal line 16 can diffuse into the metal pad 20 via the metal barrier 18. Also, the adhesive strength between the metal barrier 18 and the Al pad is deteriorated because the surface conditions of the metal barrier 18 are unstable after deposition. The deterioration of the adhesiveness between the metal barrier 18 and the Al pad becomes a greater problem when the contact surface of the metal barrier 18 and the metal pad 20 is large. Moreover, cracks can occur inside of these layers, because of heavy stresses between the metal barrier 18 and the Al pad 20.

### SUMMARY

Consistent with embodiments of the present invention, there is provided a method for manufacturing a metal pad in a semiconductor device, wherein the surface of the metal barrier interposed between a Cu metal line and an Al metal pad is reformed, thus enabling the blocking of diffusion of Cu atoms in a Cu metal line into an Al pad more effectively.

Further consistent with the present invention, there is provided a method for manufacturing a metal pad in a semiconductor device that can improve the adhesiveness between a metal barrier and a metal pad by stabilizing the surface of a metal barrier.

Accordingly, an embodiment consistent with the present invention provides a method for manufacturing a metal pad in a semiconductor device which is connected to a metal line according to the present invention. The invention includes forming an interlevel dielectric (ILD) layer on a substrate; forming at least one metal line on the ILD layer; forming a metal barrier on the ILD layer and the metal line; reforming the surface of the metal barrier by performing a reforming process using an inert gas; and forming a metal pad on the metal barrier.

### BRIEF DESCRIPTION OF DRAWINGS

Referring to these drawings, a method for manufacturing a metal pad in a semiconductor device will be explained in detail.

FIG. 1 is a flow chart illustrating a conventional method for manufacturing a metal pad in a semiconductor device, according to the prior art.

FIGS. 2A to 2D are cross-sectional views illustrating conventional processes for manufacturing a metal pad in a semiconductor device, according to the prior art.

FIG. 3 is a flow chart illustrating a method for manufacturing a metal pad in a semiconductor device, consistent with the present invention.

FIGS. 4A to 4E are cross-sectional views illustrating processes for manufacturing a metal pad in a semiconductor device, consistent with the present invention.

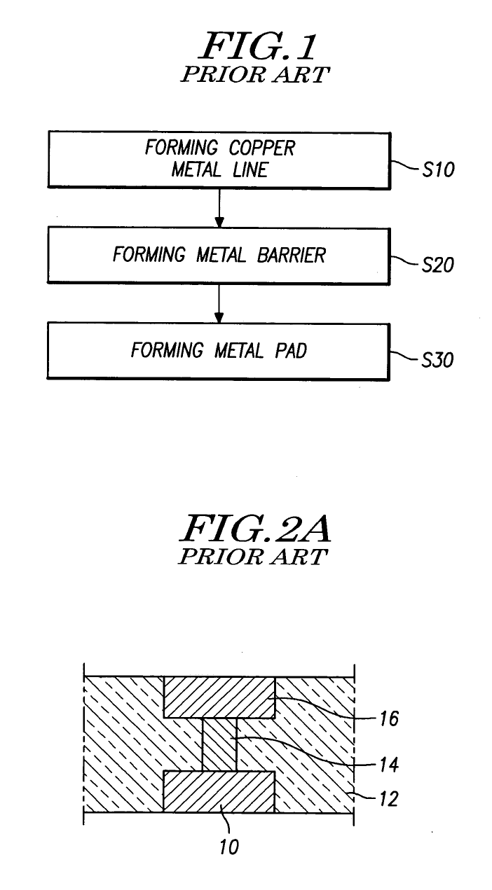

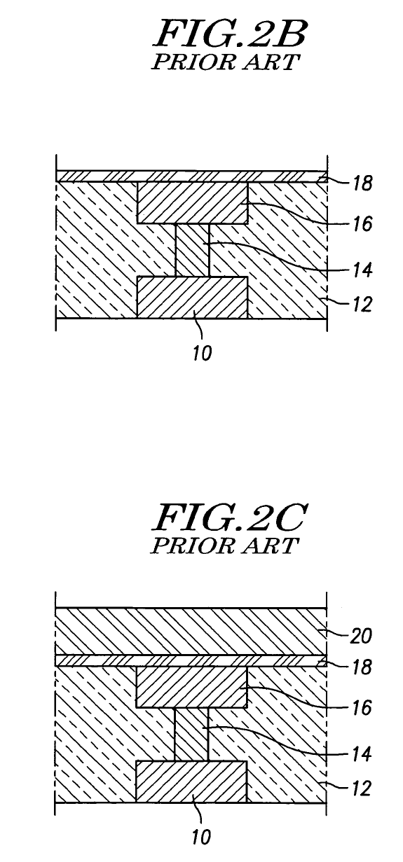

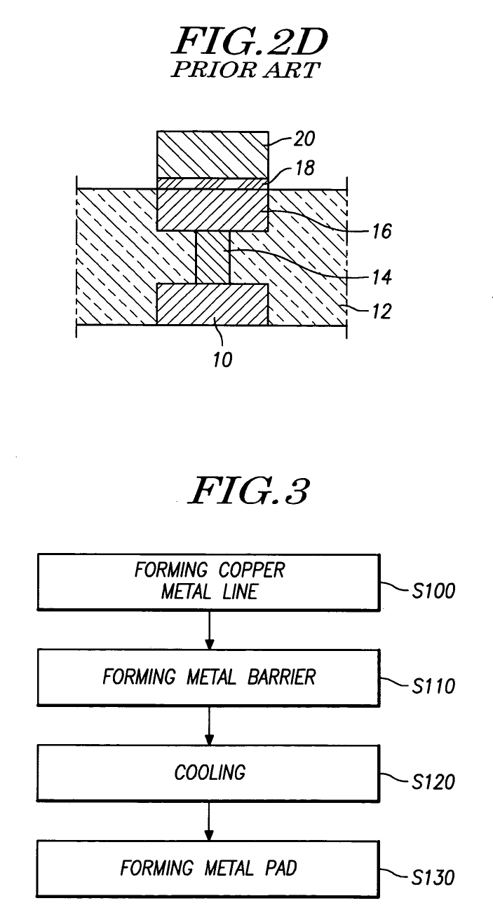

### DETAILED DESCRIPTION

These and other aspects consistent with the present invention will become evident by reference to the following description, often referring to the accompanying drawings.

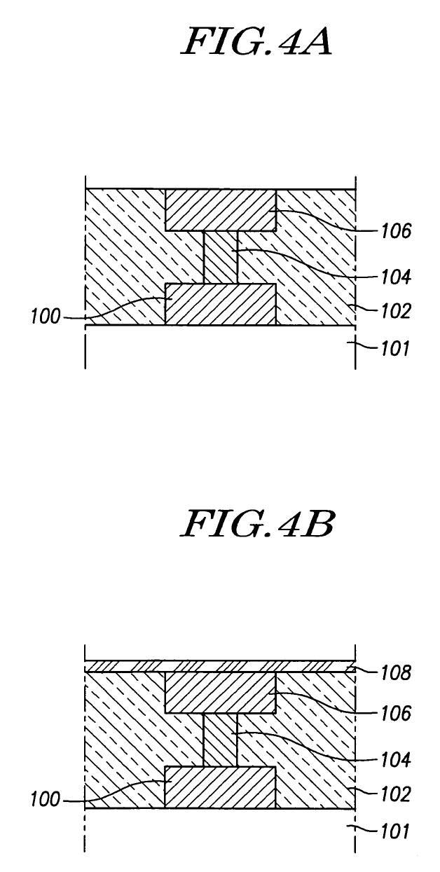

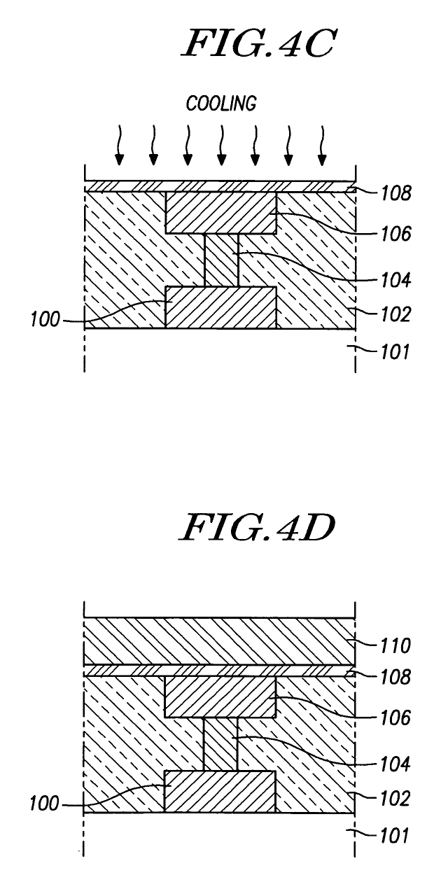

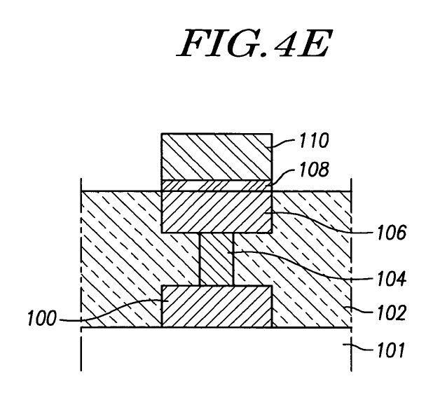

FIG. 3 is a flow chart illustrating a method for manufacturing a metal pad in a semiconductor device, consistent with the present invention. FIGS. 4A to 4E are cross-sectional views illustrating a process for manufacturing a metal pad in a semiconductor device, consistent with the present invention.

Referring to these drawings, the method for manufacturing a metal pad in a semiconductor device consistent with the present invention will be explained in detail.

Firstly, as shown in FIG. 4A, an ILD (Interlevel Dielectric) layer 102 such as a TEOS oxide layer, an HDP oxide layer, etc., is formed on a semiconductor substrate 101 in which a predetermined structure including a lower metal line 100 is formed, using a CVD or PVD process. Here, lower metal line 100 may be formed of Cu, Al, or other metal materials. Also, the structure in the semiconductor substrate may be a semiconductor device such as a MOS transistor, and the like.

Subsequently, photolithography and etching processes are performed on ILD layer 102 using a mask defining a damascene structure, thus forming a trench and a contact hole. Then, using an electroplating method, etc., the trench and the contact hole are filled with Cu, and then the Cu filled in the trench and the contact hole is planarized using a CMP process until a surface thereof is exposed, thus forming an upper Cu metal line 106 and a contact 104 connected to lower metal line 100 (step S100 of FIG. 3).

Subsequently, as shown in FIG. 4B, a metal barrier 108, e.g., a TiSiN layer, is formed on ILD layer 102 and upper Cu metal line 106, using a CVD process. (step S110 of FIG. 3) For example, a TiSiN layer can be formed using TDMAT (Tetrakis-Dimethyl-Amino-Titanium; (Ti[N(CH₃)₂]₄) and a silane (SiH₄) gas at a temperature of about 350° C. in a processing chamber.

Next, as shown in FIG. 4C, a cooling process is implemented to reform the surface of metal barrier 108 (step S120 of FIG. 3). Here, the cooling process is implemented by injecting about 20 sccm of an inert gas such as Ar, etc., in the chamber for the deposition of metal barrier 108, for about 30 seconds at a pressure of about 2.0 Torr.

By the cooling process, the surface of metal barrier 108 previously at about 350° C. can be cooled down naturally to under 350° C. Thus, the surface conditions of metal barrier 108 can be stabilized. Accordingly, the adhesive strength between metal barrier 108 and a metal pad that will be formed in the subsequent process can be improved.

Subsequently, as shown in FIG. 4D, after finishing the cooling process, an Al layer that will be used as a metal pad 110 is formed on metal barrier 108 using a PVD process.

Thereafter, as shown in FIG. 4E, Al metal pad 110 is formed by patterning the Al layer and metal barrier 108 by photolithography and etching processes using a metal pad mask.

As the above described, consistent with the present invention, the surface conditions of the metal barrier can be reformed and stabilized by the cooling process, thus, the adhesive strength between the metal barrier and the metal pad formed on the metal barrier can be improved. Also, diffusion of Cu atoms in the Cu metal line via the metal barrier into the Al metal pad can be prevented more effectively, since the surface of the metal barrier is naturally cooled down and reformed. As a result, the present invention has advantages in that the metal pad can be designed larger since stresses between the metal barrier and the metal pad can be significantly reduced even though the adhesive area between the metal barrier and the metal pad is large.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for manufacturing a metal pad connected to a metal line in a semiconductor device, comprising the steps of:
forming an interlevel dielectric (ILD) layer on a substrate;
forming at least one metal line on the ILD layer;
forming a metal barrier on the ILD layer and the metal line;
reforming a surface of the metal barrier by performing a reforming process using an inert gas; and
forming a metal pad on the metal barrier.

2. The method of claim 1, wherein the metal line is formed by a damascene process.

3. The method of claim 1, wherein the metal line comprises Cu, the metal barrier comprises TiSiN, and the metal pad comprises Al.

4. The method of claim 1, wherein the reforming process is performed within a processing chamber.

5. The method of claim 1, wherein the reforming process uses Ar.

6. The method of claim 5, wherein the reforming process is performed at a pressure of about 2.0 Torr and using 20 sccm of Ar gas.

7. The method of claim 6, wherein the reforming process is performed for approximately 30 seconds.
